(19) United States
(12) Patent Application Publication
(10) Pub. No.: US 2004/0262727 A1
(43) Pub. Date: Dec. 30, 2004

(54) Computer system implemented on flex tape

(76) Inventors: David P. McConville, Chandler, AZ (US); Steven Towle, Phoenix, AZ (US); Anna George, Phoenix, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/609,826

(22) Filed: Jun. 30, 2003

(51) Int. Cl. H01L 23/02; H01L 23/34

(52) U.S. Cl. 257/678; 257/723

(57) ABSTRACT

According to one embodiment, a system is disclosed. The system includes a first integrated circuit (IC), an input/output (I/O) signal routing layer mounted below the first IC and a second IC mounted on the routing layer. The second IC is electrically coupled to the first IC via the routing layer

### FIELD OF THE INVENTION

The present invention relates to computer systems; more particularly, the present invention relates to high speed signaling within a computer system.

### BACKGROUND

As the speed and complexity of processors and other integrated circuit components has increased, the need for high-speed input/output (I/O) has also increased. Conventional packaging technologies are reaching physical limitations making such technologies unable to meet requirements. New technologies, such as optical IO integrated on a die, are becoming a reality.

Current manufacturing processes and designs have limited ability to adapt to these new technologies. Additionally, current conventional processing of integrated circuits uses the same substrate design structure for power delivery and for signal I/O. Neither of these can be optimized, either for performance versus cost or other factors, as some of the requirements of one area restrict the optimization of the other. For instance, limitations of materials and structures of computer system motherboards, sockets, and substrates result in electrical losses and noise.

### BRIEF DESCRIPTION OF THE DRAWINGS

The present invention will be understood more fully from the detailed description given below and from the accompanying drawings of various embodiments of the invention. The drawings, however, should not be taken to limit the invention to the specific embodiments, but are for explanation and understanding only.

FIG. 1 illustrates one embodiment of a computer system

FIG. 2 illustrates one embodiment of multiple integrated circuits mounted on flex tape;

FIG. 3 illustrates a cross section of an embodiment of an integrated circuit device package;

FIG. 4 illustrates a top view of an embodiment of an input/output routing layer of an integrated circuit substrate for a two-sided connection to another integrated circuit; and

FIG. 5 illustrates another embodiment of multiple integrated circuits mounted on flex tape.

### DETAILED DESCRIPTION

A computer system on flex tape is described. In the following description, numerous details are set forth. It will be apparent, however, to one skilled in the art, that the present invention may be practiced without these specific details. In other instances, well-known structures and devices are shown in block diagram form, rather than in detail, in order to avoid obscuring the present invention.

Reference in the specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment.

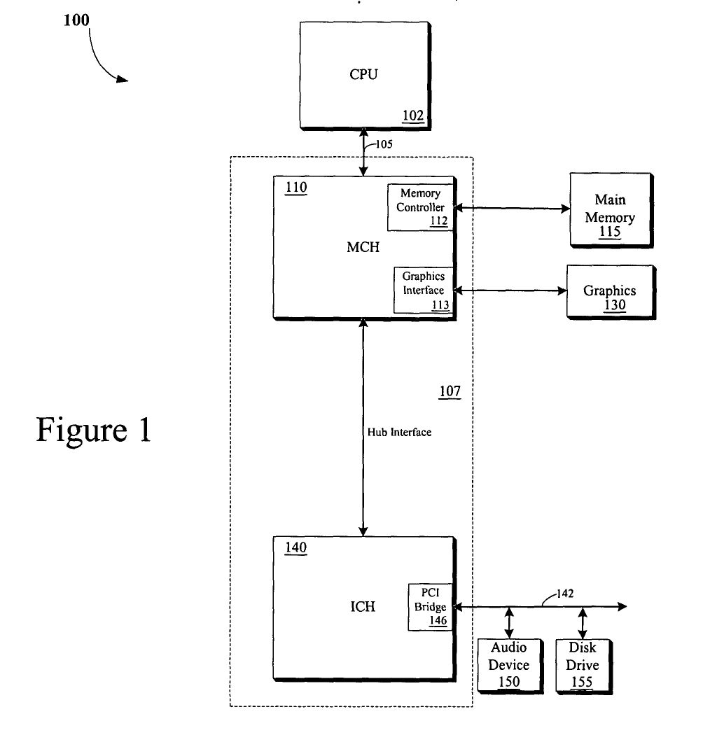

FIG. 1 is a block diagram of one embodiment of a computer system 100. Computer system 100 includes a central processing unit (CPU) 102 coupled to bus 105. In one embodiment, CPU 102 is a processor in the Pentium® family of processors including the Pentium® II processor family, Pentium® III processors, and Pentium® IV processors available from Intel Corporation of Santa Clara, Calif. Alternatively, other CPUs may be used.

A chipset 107 is also coupled to bus 105. Chipset 107 includes a memory control hub (MCH) 110. MCH 110 may include a memory controller 112 that is coupled to a main system memory 115. Main system memory 115 stores data and sequences of instructions that are executed by CPU 102 or any other device included in system 100. In one embodiment, main system memory 115 includes dynamic random access memory (DRAM); however, main system memory 115 may be implemented using other memory types. Additional devices may also be coupled to bus 105, such as multiple CPUs and/or multiple system memories.

MCH 110 may also include a graphics interface 113 coupled to a graphics accelerator 130. In one embodiment, graphics interface 113 is coupled to graphics accelerator 130 via an accelerated graphics port (AGP) that operates according to an AGP Specification Revision 2.0 interface developed by Intel Corporation of Santa Clara, Calif.

In one embodiment, MCH 110 is coupled to an input/output control hub (ICH) 140 via a hub interface. ICH 140 provides an interface to input/output (I/O) devices within computer system 100. ICH 140 may be coupled to a Peripheral Component Interconnect bus adhering to a Specification Revision 2.1 bus developed by the PCI Special Interest Group of Portland, Oreg. Thus, ICH 140 includes a PCI bridge 146 that provides an interface to a PCI bus 142. PCI bridge 146 provides a data path between CPU 102 and peripheral devices.

PCI bus 142 includes an audio device 150 and a disk drive 155. However, one of ordinary skill in the art will appreciate that other devices may be coupled to PCI bus 142. In addition, one of ordinary skill in the art will recognize that CPU 102 and MCH 110 could be combined to form a single chip. Further graphics accelerator 130 may be included within MCH 110 in other embodiments.

According to one embodiment, processor 102 and chipset 107 operate via very high bus speeds. Communicating high-speed signals through conventional architecture is a significant challenge due to electrical losses and noise resulting from limitations of the materials and structures of the motherboard, socket, and substrate (not shown) to which processor 102 and chipset 107 are connected.

According to one embodiment, the above problems are significantly reduced by connecting integrated circuits, such as processor 102 and chipset 107, by high-speed bus 105 through a flex plus rigid core hybrid substrate (flex tape). Therefore, all relevant integrated circuits are mounted on the same piece of flex tape, thereby eliminating the impedance discontinuities from connectors.

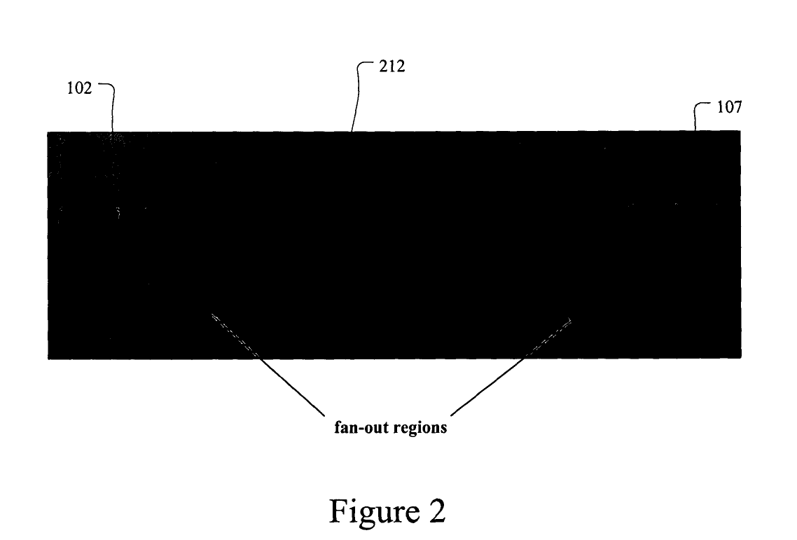

FIG. 2 illustrates one embodiment of processor 102 and chipset 107 mounted on a flex tape 107. Flex tape 212 functions as an input/output (I/O) signal routing layer through which signals are transmitted between processor 102 and chipset 107. Flex tap 212 includes traces that are electrically connected to fan-out regions.

In one embodiment, the materials of flex tape 212 are selected to be conducive with high bandwidth signals. Typically, these materials would be low-loss and low-k, k being the average dielectric constant of the material. A low k material would be a material with a dielectric constant less than 3. A low loss material would have a loss tangent of less than 0.01. In a further embodiment, flex tape 12 has one or two layers. In the embodiment of a two-layer flex tape, the top metal layer 12a would be the signal transmission layer to carry the signals, and the bottom layer 12b is used as a reference plane. A one-layer flex tape may comprise only layer 12b and may be a layer of dielectric material.

In yet another embodiment, flex tape 212 is constructed of a low-k polyimide material. Further, the tape 212 material will be inherently more flexible than typical organic build-up layers currently in use. This may minimize the stresses on the mechanically weak silicon using ultra low k dielectric. In addition, the material being more compliant and flexible may lead to an overall more structurally sound package. One of ordinary skill in the art will appreciate that other materials may be implemented without departing from the true scope of the invention.

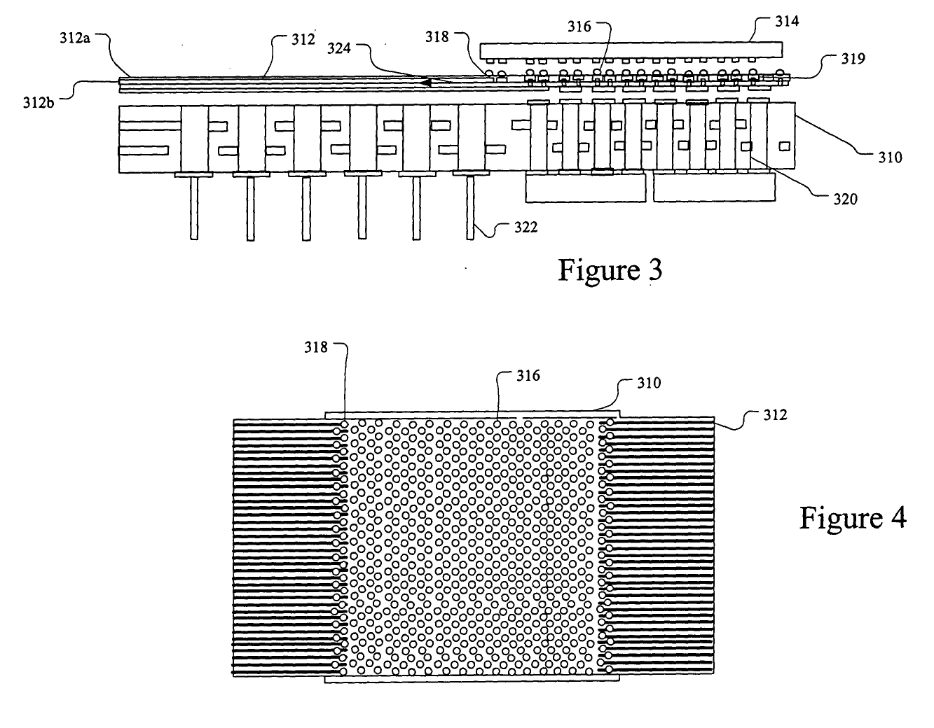

FIG. 3 illustrates a cross section of an embodiment of an integrated circuit device package mounted on flex tape 212. A substrate core 310 has a design optimized for power delivery through power paths 320 and pins 322. It must be noted that pins of a pin grid array may also be replaced by a ball grid array or land grid array, all of which would serve as package connectors. This is intended as an example as a means for better understanding of the invention and is not intended to limit application of embodiments of the invention. One of ordinary skill in the art would appreciate that any type of package connectors could be used.

Flex tape 212 is arranged on the substrate core to allow routing of the I/O signals and pass through vias for power delivery. As discussed above, flex tape 212 serves as an I/O signal routing layer. Vias and pads are provided on the two-layered flex tape 212 to enable contact between the power delivery part integrated circuit die 314 and the power paths such as 320 through the solder balls 316.

Solder ball 318 is in contact with the I/O signaling components of the integrated circuit and allows routing of the I/O signals in a direction perpendicular to the power paths, such as in the direction 324, where the signals are routed horizontally out from the edge of the silicon die. The routing layer may encompass newer I/O technologies, such as optical waveguides or an optical routing, as well as electromagnetic signaling, acting as an electromagnetic routing layer.

This allows separation of the power delivery and I/O signals, and avoids having to route the I/O signals through the substrate core. This also allows the power delivery design to be optimized without accounting for signal I/O and reduces impedance mismatch and discontinuities in the I/O signals. Alternative methods of power delivery through the core substrate could also be used. In one embodiment, power delivery could be accomplished by integrated power delivery through the substrate, rather than through the power paths.

A top view of a substrate core 310 upon which is arranged a flex tape 212 is shown in FIG. 4. Flex tape 212 may have drilled and plated vias, through which the solder balls 316 and 318 make connection to the integrated circuit. Note that the solder ball 18 will rest on a trace that causes the signals from the I/O portions of the circuit to route to the side. Solder ball 316 would provide connection for power delivery through the substrate core. In this manner, due to the depopulation of the signal pins, which no longer go through the substrate core, more pins are provided for power delivery, allowing better power delivery for a given package body size.

Flex tape 212 continues on past substrate 310 so that one or more other integrated circuits may be mounted thereon in alignment with the traces that form the signal paths 313. Thus, the I/O signals may be routed on and off the device, and provides a high performance bus to connect to other devices.

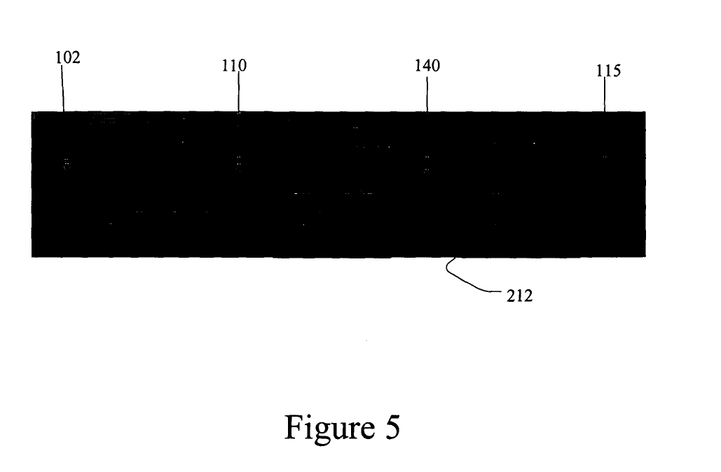

FIG. 5 illustrates one embodiment of multiple integrated circuits mounted on flex tape. In this embodiment, processor 102, MCH 110, memory 115 and ICH 140 are all mounted on flex tape 212 to facilitate the routing of high-speed signals between the components. Although described with reference to a computer system, the above described system on flex tape may also be implemented in wireless devices, communications devices, optical devices, and any other types of devices.

The above-described invention provides for lower electrical losses than traditional pinned connectors due to low-k and low tan-delta of flex dielectric materials. In addition, minimal impedance discontinuities and no coupling of power supply noise to signals exist.

Whereas many alterations and modifications of the present invention will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims which in themselves recite only those features regarded as the invention.

1. A system comprising:
a first integrated circuit (IC);
an input/output (I/O) signal routing layer mounted below the first IC, the I/O signal routing layer including:
a signal transmission layer to transmit I/O signals: and a reference plane; and
a second IC mounted on the routing layer and electrically coupled to the first IC via the routing layer;

2. The system of claim 1 further comprising a substrate core mounted below the routing layer and electrically coupled to the first IC and the second IC via the routing layer.

3. The system of claim 1 further comprising a third IC mounted on the routing layer and electrically coupled to the second IC via the routing layer.

4. The system of claim 3 wherein the first IC is a processor, the second IC is a chipset and the third IC is a memory device.

5. The system of claim 1 wherein the signal routing layer comprises a flexible tape.

6. The system of claim 5 wherein the signal transmission layer comprises an optical waveguide.

7. The system of claim 5 wherein the flexible tape comprises polyimide.

8. The system of claim 2 wherein the signal transmission layer comprises one or more vias to receive power from the substrate core.

9. The system of claim 1 wherein the signal layer comprises a laminate tape.

10. A system comprising:
a first integrated circuit (IC);
an input/output (I/O) signal routing layer mounted below the first IC, the signal routing layer comprising:
a signal transmission layer to transmit I/O signals;
a reference layer to operate as a reference plane; and
a flex connector to provide electrical coupling between the first and second routing layer; and
a second IC mounted on the routing layer and electrically coupled to the first IC via the first and second routing layers;

11. The system of claim 10 wherein the first and second layers comprise a flexible tape.

12. The system of claim 10 wherein the first and second routing layers further comprise a laminate tape.

13. A system comprising:
a core substrate having power paths;
a routing layer having signal paths arranged so as to be decoupled from the power paths.
a first integrated circuit (IC) mounted on the routing layer;
a second IC mounted on the routing layer and electrically coupled to the first IC via the routing layer;

14. The system of claim 13 further comprising a third IC mounted on the routing layer and electrically coupled to the second IC via the routing layer.

15. The system of claim 14 wherein the first IC is a processor, the second IC is a chipset and the third IC is a memory.

16. The system of claim 13 wherein the routing layer comprises a flexible tape.

17. The system of claim 13 wherein the routing signals are routed in a direction perpendicular to the power paths.

18. The system of claim 13 wherein the routing signals are routed horizontally from the first IC and the second IC.
